(19) United States
(12) Patent Application Publication
(10) Pub. No.: US 2026/0026054 A1
(43) Pub. Date: Jan. 22, 2026

(54) SEMICONDUCTOR DEVICE AND PREPARATION METHOD THEREFOR

(71) Applicant: CSMC TECHNOLOGIES FAB2 CO., LTD., Wuxi (CN)

(72) Inventors: Teng LIU, Wuxi (CN); Nailong HE, Wuxi (CN); Hua SONG, Wuxi (CN); Zhili ZHANG, Wuxi (CN); Wentong ZHANG, Wuxi (CN); Tianlong WEN, Wuxi (CN)

(21) Appl. No.: 18/879,607

(22) PCT Filed: Jul. 11, 2023
(86) PCT No.: PCT/CN2023/106701

§ 371 Date: Dec. 27, 2024

(30) Foreign Application Priority Data
Jul. 12, 2022 (CN) 202210817094.6

(51) Int. Cl. H10D 62/10; H10D 30/01; H10D 30/65; H10D 62/83

(52) U.S. Cl. CPC H10D 62/115; H10D 30/0281; H10D 30/657; H10D 62/103; H10D 62/83

(57) ABSTRACT

The present application relates to a semiconductor device and a preparation method therefor. The semiconductor device includes a semiconductor substrate, an insulating buried layer, a drift region, and a plurality of dielectric isolation structures. The insulating buried layer is located on the semiconductor substrate. The drift region is located on the insulating buried layer. A drain region is provided on part of the upper surface of the drift region. The plurality of dielectric isolation structures are located in the drift region and on the insulating buried layer, and are spaced apart from each other in a direction towards the drain region. At least one dielectric isolation structure protrudes from the insulating buried layer and is bent towards the drain region.

### CROSS-REFERENCE TO RELATED APPLICATIONS

This application claims priority to Chinese Patent Application No. 202210817094.6, entitled “SEMICONDUCTOR DEVICE AND MANUFACTURING METHOD FOR THE SAME” and filed on Jul. 12, 2022, the entire content of which is incorporated herein by reference.

### TECHNICAL FIELD

The present disclosure relates to the field of semiconductor technologies, and in particular, to a semiconductor device and a manufacturing method for the same.

### BACKGROUND

A semiconductor on insulator (SOI) device has a higher operating speed, higher integration, better insulation performance, stronger radiation resistance, and a better self-locking effect. Therefore, the SOI device has received widespread attention in the field of very large-scale integrated circuits.

However, conventional SOI devices have shortcomings such as a low breakdown voltage and poor heat dissipation performance.

### SUMMARY

According to various embodiments of the present disclosure, a semiconductor device and a manufacturing method for the same are provided to solve at least one of the above technical problems.

To achieve the object of the present disclosure, the present disclosure adopts the following technical solutions.

A semiconductor device, includes a semiconductor substrate, an insulating buried layer, a drift region, and a plurality of dielectric isolation structures. The insulating buried layer is located on the semiconductor substrate. The drift region is located on the insulating buried layer. Part of an upper surface layer of the drift region is provided with a drain region. The plurality of dielectric isolation structures are located in the drift region and on the insulating buried layer, and spaced apart in a direction towards the drain region. At least one of the dielectric isolation structures protrudes from the insulating buried layer and bends towards the drain region.

In an embodiment, each of the dielectric isolation structures protrudes from the insulating buried layer and bends towards the drain region.

In an embodiment, each dielectric isolation structure protruding from the insulating buried layer and bending towards the drain region includes a support portion and a barrier portion. An end of the support portion is in direct contact with the insulating buried layer, another end of the support portion is connected to an end of the barrier portion, another end of the barrier portion bends and extends towards the drain region. The barrier portion is spaced apart from the insulating buried layer.

In an embodiment, the barrier portion is parallel to the insulating buried layer.

In an embodiment, the support portion and the barrier portion are connected in an arc shape or perpendicularly.

In an embodiment, the plurality of dielectric isolation structures include a plurality of first dielectric isolation structures and at least one second dielectric isolation structure. Heights of the first dielectric isolation structures are all less than a height of the at least one second dielectric isolation structure. The at least one second dielectric isolation structure is arranged on a side of the plurality of dielectric isolation structures away from the drain region. The second dielectric isolation structure semi-encloses at least one of the first dielectric isolation structures.

In an embodiment, the plurality of dielectric isolation structures include a plurality of second dielectric isolation structures. The farther the second dielectric isolation structure is away from the drain region, the higher the height of the second dielectric isolation structure is.

In an embodiment, a projection of each second dielectric isolation structure on the insulating buried layer has an overlapping region with a projection of at least one of the first dielectric isolation structures adjacent to the second dielectric isolation structure on the insulating buried layer.

In an embodiment, each of the dielectric isolation structures includes a support portion and a barrier portion. An end of the support portion is in direct contact with the insulating buried layer, another end of the support portion is connected to an end of the barrier portion, another end of the barrier portion bends and extends towards the drain region. The barrier portion is spaced apart from the insulating buried layer. A height of the support portion of the second dielectric isolation structure is greater than that of the support portion of the first dielectric isolation structure. The height of the support portion is a dimension of the support portion in a thickness direction of the semiconductor device.

In an embodiment, each of the dielectric isolation structures includes a support portion and a barrier portion. An end of the support portion is in direct contact with the insulating buried layer, another end of the support portion is connected to an end of the barrier portion, another end of the barrier portion bends and extends towards the drain region. The barrier portion is spaced apart from the insulating buried layer. A length of the barrier portion of the second dielectric isolation structure is greater than that of the barrier portion of the first dielectric isolation structure. The length of the barrier portion is a dimension of the barrier portion in a direction towards the drain region.

In an embodiment, dielectric constants of at least two of the dielectric isolation structures gradually decrease in the direction towards the drain region; or the plurality of the dielectric isolation structures are arranged to form a first dielectric isolation group, a second dielectric isolation group, and a third dielectric isolation group that are spaced apart in the direction towards the drain region. A dielectric constant of each of the dielectric isolation structures in the first dielectric isolation group is greater than that of each of the dielectric isolation structures in the second dielectric isolation group. The dielectric constant of each of the dielectric isolation structures in the second dielectric isolation group is greater than that of each of the dielectric isolation structures in the third dielectric isolation group.

In an embodiment, the semiconductor device further includes: a first well region, a second well region, a first well region lead-out region, a source region, and a gate structure. The first well region and the second well region are arranged on part of the upper surface layer of the drift region. The first well region lead-out region and the source region are arranged on an upper surface layer of the first well region. The first well region lead-out region is short-circuited with potential of the source region. The drain region is arranged on an upper surface layer of the second well region. The gate structure is arranged on the first well region, and has an end extending to be above the drift region and another end extending to be above the source region. All the dielectric isolation structures are arranged between the source region and the drain region. The first well region and the first well region lead-out region have a first conductivity type. The drift region, the second well region, the source region, and the drain region have a second conductivity type. The first conductivity type and the second conductivity type are opposite.

A manufacturing method for a semiconductor device, includes: providing a semiconductor substrate; forming an insulating buried layer on the semiconductor substrate; forming a plurality of dielectric isolation structures spaced apart on the insulating buried layer; forming a drift region on the insulating buried layer, and enabling the plurality of dielectric isolation structures to be located in the drift region; and forming a drain region on part of an upper surface layer of the drift region. The plurality of dielectric isolation structures are spaced apart in a direction towards the drain region, and at least one of the dielectric isolation structures protrudes from the insulating buried layer and bends towards the drain region.

In an embodiment, forming the plurality of dielectric isolation structures spaced apart on the insulating buried layer includes: forming a dielectric isolation layer on the insulating buried layer; and etching the dielectric isolation layer to form the plurality of dielectric isolation structures spaced apart.

In an embodiment, forming the plurality of dielectric isolation structures spaced apart on the insulating buried layer includes: forming a silicon layer on the insulating buried layer; etching the silicon layer to form a plurality of trenches spaced apart in the silicon layer; and covering the silicon layer with a dielectric isolation material, filling each of the trenches with the dielectric isolation material, and etching the dielectric isolation material to form the dielectric isolation structures.

Details of one or more embodiments of the present disclosure are set forth in the following accompanying drawings and descriptions. Other features, objects, and advantages of the present disclosure become obvious with reference to the detailed description, the accompanying drawings, and the claims.

### BRIEF DESCRIPTION OF THE DRAWINGS

By reading detailed descriptions of the following preferred implementations, various other advantages and benefits may be appreciated by those of ordinary skill in the art. At the same time, in order to better describe and illustrate embodiments and/or examples of those contents disclosed herein, reference may be made to one or more accompanying drawings. Additional details or examples used to describe the accompanying drawings should not be considered as limitations on the scope of any of the disclosed contents, the presently described embodiments and/or examples, and the presently understood best mode of these contents.

FIG. 1 is a schematic structural diagram of a semiconductor device according to an embodiment.

FIG. 2 is a schematic structural diagram of a semiconductor device according to another embodiment.

FIG. 3 is a front view of a semiconductor device according to one or more embodiments.

FIG. 4 is a schematic structural diagram of a dielectric isolation structure of the semiconductor device according to one or more embodiments.

FIG. 5 is a schematic structural diagram of a semiconductor device according to yet another embodiment.

FIG. 6 is a schematic structural diagram of a semiconductor device according to still another embodiment.

FIG. 7 is a schematic flowchart of a manufacturing method for a semiconductor device according to a first embodiment.

FIG. 8 is a schematic flowchart of the manufacturing method for a semiconductor device according to the first embodiment.

FIG. 9 is a schematic flowchart of a manufacturing method for a semiconductor device according to a second embodiment.

FIG. 10 is a schematic flowchart of a manufacturing method for a semiconductor device according to a third embodiment.

In the drawings, 111: semiconductor substrate; 112: insulating buried layer; 120: drift region; 130: dielectric isolation structure; 131: first dielectric isolation structure; 132: second dielectric isolation structure; 1301: support portion; 1302: barrier portion; 133: opening; 130a: first dielectric isolation group; 130b: second dielectric isolation group; 130c: third dielectric isolation group; 140: source region; 150: drain region; 160: gate structure; 161: field oxide layer; 162: gate; 171: first well region; 172: first well region lead-out region; 180: second well region.

### DETAILED DESCRIPTION

Embodiments of technical solutions of the present disclosure will be described in detail below with reference to the accompanying drawings. The following embodiments are merely intended for a clearer description of the technical solutions of the present disclosure and therefore are used as just examples which cannot constitute any limitations on the protection scope of the present disclosure.

Unless otherwise defined, all technical and scientific terms used herein shall have the same meanings as commonly understood by those skilled in the art to which the present disclosure belongs. The terms used herein are intended to merely describe specific embodiments rather than to limit the present disclosure. The terms “include/comprise” and “have” and any other variations thereof in the specification, claims, and brief description of drawings of the present disclosure are intended to cover non-exclusive inclusions.

In the description of the embodiments of the present disclosure, the technical terms “first”, “second” and the like are merely intended to distinguish different objects, and shall not be understood as an indication or implication of relative importance or implicit indication of the number, specific sequence or dominant-subordinate relationship of the technical features indicated. In the description of the embodiments of the present disclosure, “a plurality of” means at least two unless otherwise explicitly and specifically defined.

The term “embodiment” described herein means that specific features, structures, or characteristics described in combination with the embodiments may be incorporated in at least one embodiment of the present disclosure. The phase appearing in various places in the specification does not necessarily refer to the same embodiment or an independent or alternative embodiment that is exclusive of other embodiments. It is explicitly or implicitly understood by those skilled in the art that the embodiments described herein may be combined with other embodiments.

It should be understood that when an element or layer is referred to as being “on”. “adjacent to”, “connected to”, or “coupled to” another element or layer, the element or layer may be directly on, adjacent to, connected to, or coupled to the another element or layer, or an intermediate element or layer may be disposed therebetween. On the contrary, when an element is referred to as being “directly on”, “directly adjacent to”, “directly connected to”, or “directly coupled to” another element or layer, no intermediate element or layer may be disposed therebetween. It should be understood that although terms such as first, second, and third may be used to describe various elements, components, regions, layers, and/or portions, the elements, components, regions, layers, and/or portions may not be limited to such terms. Such terms are used only to distinguish one element, component, region, layer, or portion from another element, component, region, layer, or portion. Thus, without departing from the teaching of the present disclosure, a first element, component, region, layer, or portion may be referred to as a second element, component, region, layer, or portion.

Spatial relationship terms such as “under”, “underneath”, “below”, “beneath”, “over”, and “above” may be used for illustrative purposes for easy description, to describe a relationship between one element or feature and another element or feature illustrated in the figures. It should be understood that, in addition to the orientations illustrated in the figures, the spatial relationship terms are intended to further include different orientations of the device in use and operation. For example, if the device in the figures is turned over, the element or feature described as being “below”, “underneath” or “under” another element or feature may be oriented as being “on” the another element or feature. Thus, the exemplary terms “below” and “under” may include two orientations of above and below. In addition, the device may include additional orientations (e.g., be rotated by 90 degree or oriented in other ways), and thus spatial descriptors used herein may be interpreted accordingly.

The terms used herein are for the purpose of describing specific embodiments only and are not intended to limit the present disclosure. In use, the singular forms of “a/an”, “one”, and “the” may also include plural forms, unless otherwise clearly specified in the context. It should be further understood that the terms “consist of” and/or “include/comprise”, when used in the specification, specify the presence of the features, integers, steps, operations, elements, components, and/or groups, but may not exclude the presence or addition of one or more of other features, integers, steps, operations, elements, components, and/or groups. Herein, in use, the term “and/or” may include any and all combinations of associated listed items.

Embodiments of the present disclosure are described herein with reference to cross-sectional views of schematic diagrams of ideal embodiments (and intermediate structures) of the present disclosure. Correspondingly, variations of the illustrated shape caused by, for example, manufacturing techniques and/or tolerances, may be expected. Thus, the embodiments of the present disclosure may not be limited to the specific shapes of the regions illustrated herein, but may include shape deviations caused by, for example, the manufacturing techniques. For example, an implanted region illustrated as a rectangle, typically, has rounded or curved features and/or a gradient of implant concentration at its edges rather than a binary change from an implanted region to a non-implanted region. Likewise, a buried region formed by implantation may result in some implantation in the region between the buried region and a surface through which the implantation takes place. Thus, the region shown in the drawings is generally schematic, and the illustrated shape thereof is not intended to show the actual shape of the region of the device, and is not intended to limit the scope of the present disclosure.

The vocabulary in the semiconductor field used herein is a technical vocabulary commonly used by those skilled in the art. For example, for P-type and N-type impurities, in order to distinguish doping concentration, it is simple to use P+ type to represent P type of heavy doping concentration, use P type to represent P type of medium doping concentration, use P-type to represent P type of light doping concentration, use N+ type to represent N type of the heavy doping concentration, use N type to represent N type of the medium doping concentration, and use N-type to represent N type of the light doping concentration.

After research and development, it is found that, in a silicon-on-insulator (SOI) high-voltage device, taking an N-type laterally diffused metal oxide semiconductor (LDMOS) as an example, on the one hand, a depletion layer formed by a P-type well region and a drift region continues to expand. On the other hand, an insulating buried layer and a semiconductor substrate form an inverted metal-insulator-semiconductor (MIS) structure. When a reverse voltage increases to a certain level, a depletion layer formed at an interface between the drift region and the insulating buried layer in the inverted MIS structure stops expanding, and an interface inversion layer is formed at the interface between the drift region and the insulating buried layer. When the reverse voltage continues to increase, the depletion layer, that is formed by the P-type well region and the drift region, and the depletion layer, that is formed by the insulating buried layer and the drift region merge to form a depletion region. At the same time, almost all interface charges at the interface inversion layer are extracted, resulting in a low breakdown voltage of the SOI high-voltage device.

In order to solve at least one of the foregoing technical problems, the present disclosure designs a semiconductor device, which adopts a dielectric isolation structure to greatly prevent extraction of interface charges and also to improve distribution of power lines on a surface of the device, thereby greatly increasing a withstand voltage of the device.

FIG. 1 is a schematic structural diagram of a semiconductor device according to an embodiment.

In some embodiments, referring to FIG. 1, a semiconductor device according to an embodiment of the present disclosure includes a semiconductor substrate 111, an insulating buried layer 112, a drift region 120, and a plurality of dielectric isolation structures 130. The insulating buried layer 112 is located on the semiconductor substrate 111. The drift region 120 is located on the insulating buried layer 112. Part of an upper surface layer of the drift region 120 is provided with a drain region 150. The plurality of dielectric isolation structures 130 are located in the drift region 120 and on the insulating buried layer 112 and spaced apart in a direction towards the drain region 150. At least one dielectric isolation structure 130 protrudes from the insulating buried layer 112 and bends towards the drain region 150. It may be understood that each dielectric isolation structure 130 is in contact with the insulating buried layer 112.

The following description is based on an example in which the semiconductor device is a LDMOS device. In this embodiment, part of the upper surface layer of the drift region 120 is provided with a first well region 171 and a second well region 180; a source region 140 is arranged on an upper surface layer of the first well region 171; the drain region 150 is arranged on an upper surface layer of the second well region 180; and all the dielectric isolation structures 130 are arranged between the source region 140 and the drain region 150.

The semiconductor substrate 111 and the first well region 171 have a first conductivity type. The drift region 120, the second well region 180, the source region 140, and the drain region 150 all have a second conductivity type. The first conductivity type and the second conductivity type are opposite.

One of the first conductivity type and the second conductivity type is P type, and another of the first conductivity type and the second conductivity type is N type. For example, the first conductivity type is P type, and the second conductivity type is N type. Alternatively, the first conductivity type is N type, and the second conductivity type is P type. Exemplarily, in this embodiment, the first conductivity type is P type, the second conductivity type is N type, the conductivity type of the semiconductor substrate 111 is P type, and the conductivity type of the drift region 120 is N type.

According to the above semiconductor device, on the one hand, when a reverse bias voltage is applied to the semiconductor device, a depletion layer formed by the first well region 171 and the drift region 120 may merge with a depletion layer formed by the insulating buried layer 112 and the drift region 120, an interface inversion layer may also be formed on an upper surface of the insulating buried layer 112. Interface charges are formed in the interface inversion layer. Since at least one dielectric isolation structure 130 protrudes from the insulating buried layer 112 and bends towards the drain region 150, it may be understood that the dielectric isolation structure 130 is configured to block the interface charges formed on the upper surface of the insulating buried layer 112 between two adjacent dielectric isolation structures 130, and configured to block the interface charges between the dielectric isolation structure 130 and the insulating buried layer 112. In this way, the interface charges in the interface inversion layer can be blocked between two adjacent dielectric isolation structures 130 and between the dielectric isolation structure 130 and the insulating buried layer 112. When the depletion region expands on a large scale, a capability to block interface inverse charges can be effectively improved, and a dielectric electric field of the insulating buried layer 112 can be increased. In addition, due to a shielding effect of the interface charges, a strong electric field in the drain region 150 may be reduced, which prevents the source region 140 from being broken down before the electric field of the drain region 150 rises, helping improve a lateral voltage withstand capability of the semiconductor device.

In addition, the plurality of dielectric isolation structures 130 are spaced apart in the drift region 120 in a direction towards the drain region 150. It may be understood that the dielectric isolation structure 130 protruding from the insulating buried layer 112 and bending towards the drain region 150 is equivalent to a layer of SOI structure, so that the dielectric isolation structure 130 and the insulating buried layer 112 can form a dual dielectric withstand voltage layer, and thus a vertical voltage withstand capability of the semiconductor device can be greatly improved. Therefore, by use of the plurality of dielectric isolation structures 130, the lateral voltage withstand capability and the vertical voltage withstand capability of the semiconductor device can be improved, and a breakdown voltage of the semiconductor device can be ultimately increased.

It should be noted that the above description is merely based on the LDMOS device, and “the plurality of dielectric isolation structures 130” are also applicable to other types of semiconductor devices, which can greatly improve the lateral voltage withstand capability and the vertical voltage withstand capability of the semiconductor device.

Wording “at least one dielectric isolation structure 130 protrudes from the insulating buried layer 112 and bends towards the drain region 150” may mean that one dielectric isolation structure 130 protrudes from the insulating buried layer 112 and bends towards the drain region 150, or two dielectric isolation structures 130 protrude from the insulating buried layer 112 and bend towards the drain region 150, or all the dielectric isolation structures 130 protrude from the insulating buried layer 112 and bend towards the drain region 150, which is not specifically limited herein. FIG. 1 to FIG. 3 and FIG. 5 show examples in which all the dielectric isolation structures 130 protrude from the insulating buried layer 112 and bend towards the drain region 150.

In some embodiments, in the plurality of dielectric isolation structures, three dielectric isolation structures 130 closer to the drain region 150 protrude from the insulating buried layer 112 and bend towards the drain region 150, and the remaining dielectric isolation structures 130 do not bend.

In some embodiments of the present disclosure, referring to FIG. 1 to FIG. 3, the dielectric isolation structures 130 protrude from the insulating buried layer 112 and bends towards the drain region 150.

In some embodiments of the present disclosure, referring to FIG. 1 to FIG. 3, the semiconductor device further includes a gate structure 160. The gate structure 160 is arranged on the first well region 171, and has an end extending to cover the drift region 120 and another end extending to cover the source region 140. It may be understood that an edge of a projection region of the gate structure 160 on the drift region 120 overlaps with an edge of a projection region of the source region 140 on the drift region 120. On the one hand, under the control of an external voltage, a region of the first well region 171 that overlaps with the gate structure 160 is configured to form a conductive channel. On the other hand, during manufacturing the semiconductor device, the gate structure 160 may also serve as an implantation barrier layer for implantation doping into the source region 140, so that the source region 140 can perform self-aligned implantation to ensure a width of the conductive channel.

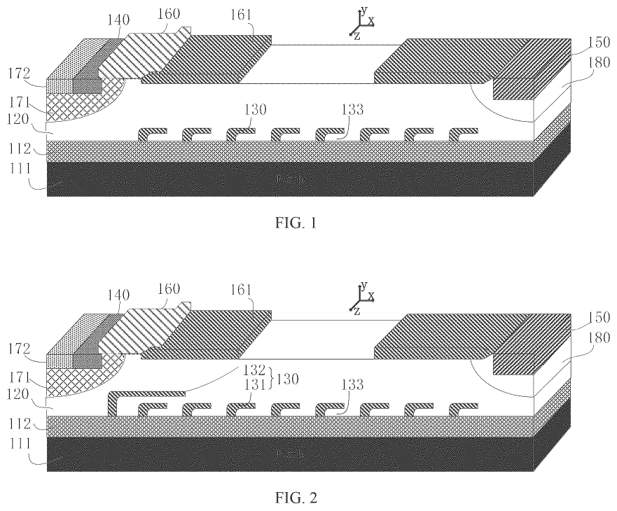

Still referring to FIG. 2, the gate structure 160 includes a gate dielectric layer and a gate 162. For example, the gate dielectric layer may be a gate oxide layer. The gate 162 may be made of a polysilicon material, metal, metal nitride, or metal silicide, which is not specifically limited herein.

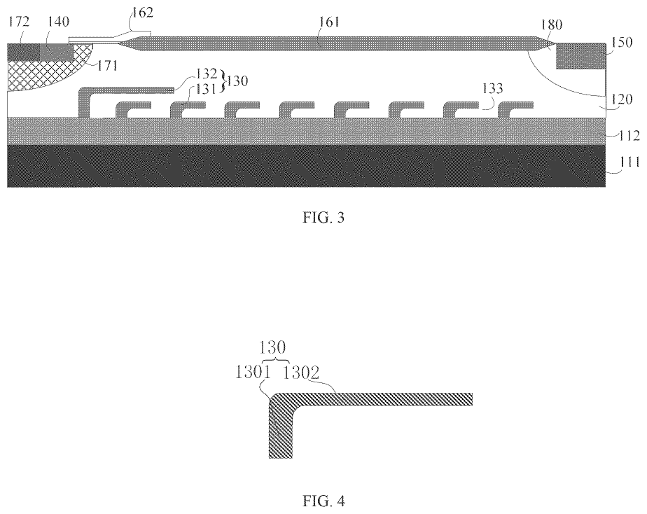

In some embodiments of the present disclosure, referring to FIG. 1 to FIG. 3, the semiconductor device further includes a field oxide layer 161. Still referring to FIG. 3, after the gate structure 160 extends to cover the drift region 120, a gate 162 in the gate structure 160 continues to extend to cover the field oxide layer 161.

In some embodiments of the present disclosure, referring to FIG. 1 to FIG. 3, the semiconductor device further includes a first well region lead-out region 172. The first well region lead-out region 172 is arranged on an upper surface layer of the first well region 171 and is short-circuited with potential of the source region 140.

The source region 140 is led out as a source electrode. It may be understood that the source region 140, the first well region lead-out region 172, and the drift region 120 jointly form a parasitic NPN transistor. The first well region lead-out region 172 of the first conductivity type is arranged on the upper surface layer of the first well region 171 of the first conductivity type, which can increase concentration of a base region of the parasitic NPN transistor. Minority carriers cannot transit to an emitter of the parasitic NPN transistor due to a reduced lifetime, thereby effectively preventing turning on of the parasitic NPN transistor at a source end.

In some embodiments of the present disclosure, the source region 140 and the first well region lead-out region 172 are both heavily doped regions, and doping concentration of the source region 140 and doping concentration of the first well region lead-out region 172 are greater than doping concentration of the first well region 171. That is, the first well region lead-out region 172 and the first well region 171 form gradually changing channel doping, which can adjust a threshold voltage, reduce resistance of the semiconductor substrate 111, prevent turning on of the parasitic NPN transistor, increase concentration of the first well region 171, shorten a channel length, reduce on resistance, and reduce an area of the device.

In some embodiments of the present disclosure, referring to FIG. 1 to FIG. 3, the semiconductor device further includes a second well region 180 arranged on the upper surface layer of the drift region 120. The second well region 180 is located on a side of the gate structure 160 facing away from the source region 140 and is spaced apart from the gate structure 160. The drain region 150 is arranged on an upper surface layer of the second well region 180. The drain region 150 is a heavily doped region, and doping concentration of the drain region 150 is greater than that of the second well region 180.

In some embodiments of the present disclosure, the drain region 150 is led out as a drain electrode. When the semiconductor device enters an off process, carriers stored in the drift region 120 due to a conductivity modulation effect generated in an on state can quickly flow to the drain electrode through the second well region 180 and the drain region 150 that are of the second conductivity type, to effectively shorten an off time.

In some embodiments of the present disclosure, referring to FIG. 1 to FIG. 3, the dielectric isolation structures 130 are spaced apart at equal intervals.

Since the dielectric isolation structures 130 are spaced apart at equal intervals, potential from the drain electrode to the source electrode can be evenly segmented, and a lateral electric field from the drain region 150 to the source region 140 can be evenly distributed, thereby increasing a lateral breakdown voltage of the device.

In some embodiments of the present disclosure, referring to FIG. 1 to FIG. 4, the dielectric isolation structure 130 protruding from the insulating buried layer 112 and bending towards the drain region 150 includes a support portion 1301 and a barrier portion 1302. An end of the support portion 1301 is in direct contact with the insulating buried layer 112, another end of the support portion 1301 is connected to an end of the barrier portion 1302. Another end of the barrier portion 1302 bends and extends towards the drain region 150. The barrier portion 1302 is spaced apart from the insulating buried layer 112.

On the one hand, the barrier portion 1302 of at least one dielectric isolation structure 130 bends and extends towards the drain region 150. Considering that the plurality of dielectric isolation structures 130 are spaced apart in the direction towards the drain region 150, it may be understood that the barrier portion 1302 of the dielectric isolation structure 130 protruding from the insulating buried layer 112 and bending towards the drain region 150 is equivalent to a layer of SOI structure, so that the barrier portion 1302 and the insulating buried layer 112 can form dual dielectric withstand voltage layers, and thus a vertical voltage withstand capability of the semiconductor device can be greatly improved.

On the other hand, since the barrier portion 1302 of the dielectric isolation structure 130 protruding from the insulating buried layer 112 and bending towards the drain region 150 is spaced apart from the insulating buried layer 112, it may be understood that the dielectric isolation structure 130 protruding from the insulating buried layer 112 and bending towards the drain region 150 semi-encloses the interface charges formed on the upper surface of the insulating buried layer 112. Based on electrical isolation characteristics of the dielectric isolation structure 130, the interface charges can be blocked between the dielectric isolation structure 130 and the insulating buried layer 112 and can also be blocked between two adjacent dielectric isolation structures 130 by using the dielectric isolation structure 130 protruding from the insulating buried layer 112 and bending towards the drain region 150, which can further effectively increase the dielectric electric field of the insulating buried layer 112 and further improve the lateral voltage withstand capability of the semiconductor device.

In some embodiments of the present disclosure, the barrier portion 1302 is parallel to the insulating buried layer 112. In this way, it is beneficial for the barrier portions 1302 of the plurality of dielectric isolation structures 130 and the insulating buried layer 112 to form a dual dielectric withstand voltage layer, which can greatly improve the vertical voltage withstand capability of the semiconductor device.

In some embodiments of the present disclosure, the insulating buried layer 112 and each dielectric isolation structure 130 are both made of silicon oxide, such as silicon dioxide.

In some embodiments of the present disclosure, the support portion 1301 and the barrier portion 1302 are connected in an arc shape or perpendicularly.

The support portion 1301 and the barrier portion 1302 may be connected in an arc shape or perpendicularly, which may be selected according to a specific process requirement.

In some embodiments of the present disclosure, referring to FIG. 2 and FIG. 3, the plurality of dielectric isolation structures 130 protruding from the insulating buried layer 112 and bending towards the drain region 150 include a plurality of first dielectric isolation structures 131 and at least one second dielectric isolation structure 132. Heights of the first dielectric isolation structures 131 are all less than a height of the second dielectric isolation structure 132. The second dielectric isolation structure 132 is arranged on a side of the plurality of dielectric isolation structures 130 away from the drain region 150, and the second dielectric isolation structure 132 semi-encloses at least one first dielectric isolation structure 131.

The second dielectric isolation structure 132 farther away from the drain region 150 can effectively prevent strong extraction of inversion layer charges at the source end of the device, which can form a further blocking effect, and which can better block the interface charges between the second dielectric isolation structure 132 and the first dielectric isolation structure 131 adjacent to the second dielectric isolation structure 132 or between two adjacent second dielectric isolation structures 132, thereby better preventing extraction of the interface charges. Moreover, the interface charges blocked between the second dielectric isolation structure 132 and the first dielectric isolation structure 131 adjacent to the second dielectric isolation structure 132 or the interface charges blocked between two adjacent second dielectric isolation structures 132 can well bear part of the electric field generated by the charges at the source end, so as to effectively improve the lateral voltage withstand capability of the semiconductor device.

The plurality of dielectric isolation structures 130 may include one second dielectric isolation structure 132 protruding from the insulating buried layer 112 and bending towards the drain region 150. The second dielectric isolation structure 132 semi-encloses one first dielectric isolation structure 131 or a plurality of first dielectric isolation structures 131. In the embodiments shown in FIG. 2 and FIG. 3, the first dielectric isolation structure 131 has a structure protruding from the insulating buried layer 112 and bending towards the drain region 150. In other embodiments, the first dielectric isolation structure 131 may alternatively have a structure protruding from the insulating buried layer 112 but not bending. Certainly, the plurality of dielectric isolation structures 130 may alternatively include a plurality of second dielectric isolation structures 132 protruding from the insulating buried layer 112 and bending towards the drain region 150, which is not specifically limited herein.

In some embodiments of the present disclosure, the plurality of dielectric isolation structures 130 include a plurality of second dielectric isolation structures 132, and the farther the second dielectric isolation structure 132 is away from the drain region 150, the higher the height of the second dielectric isolation structure 132 is.

An entirety formed by the plurality of second dielectric isolation structures 132 protruding from the insulating buried layer 112 and bending towards the drain region 150 may semi-enclose one first dielectric isolation structure 131 or a plurality of first dielectric isolation structures 131 or all the first dielectric isolation structures 131, which is not specifically limited herein.

With such arrangement, when a certain number of layers of dielectric isolation structures 130 protruding from the insulating buried layer 112 and bending towards the drain region 150 are provided, a corresponding number of layers of dielectric withstand voltages are increased, which can further improve voltage withstand performance of the semiconductor device. Certainly, the number of layers of the dielectric isolation structures 130 protruding from the insulating buried layer 112 and bending towards the drain region 150 may be set in consideration of heat dissipation performance of the semiconductor device.

In some embodiments of the present disclosure, referring to FIG. 1 to FIG. 3, each dielectric isolation structure 130 protruding from the insulating buried layer 112 and bending towards the drain region 150 is provided with an opening 133 facing towards the drain region 150. Taking two adjacent first dielectric isolation structures 131 protruding from the insulating buried layer 112 and bending towards the drain region 150 as an example, the two adjacent first dielectric isolation structures 131 include a left first dielectric isolation structure 131 and a right first dielectric isolation structure 131. Interface charges on the right side of the right first dielectric isolation structure 131 are blocked between the two adjacent first dielectric isolation structures 131 through the opening 133 of the left first dielectric isolation structure 131.

In some embodiments of the present disclosure, referring to FIG. 2 and FIG. 3, a projection of the second dielectric isolation structure 132 protruding from the insulating buried layer 112 and bending towards the drain region 150 on the insulating buried layer 112 has an overlapping region with a projection of at least one first dielectric isolation structure 131 protruding from the insulating buried layer 112 and bending towards the drain region 150 that is adjacent to the second dielectric isolation structure 132, on the insulating buried layer 112. With such arrangement, it is beneficial for the interface charges between at least one first dielectric isolation structure 131 adjacent to the second dielectric isolation structure 132 and the insulating buried layer 112 to stay between the second dielectric isolation structure 132 and the insulating buried layer 112 during extraction, so as to reduce the strong electric field of the drain region 150 by utilizing a shielding effect of the interface charges, which effectively increases the dielectric electric field of the insulating buried layer 112 and improves the lateral voltage withstand capability of the semiconductor device.

In some embodiments of the present disclosure, referring to FIG. 2 and FIG. 3, a height of the support portion 1301 of the second dielectric isolation structure 132 protruding from the insulating buried layer 112 and bending towards the drain region 150 is greater than that of the support portion 1301 of the first dielectric isolation structure 131 protruding from the insulating buried layer 112 and bending towards the drain region 150. The height of the support portion 1301 refers to a dimension of the support portion 1301 in a thickness direction of the semiconductor device (in the embodiments as shown in FIG. 1, the thickness direction of the semiconductor device is parallel to a y-axis direction). In this way, the support portion 1301 of the second dielectric isolation structure 132 has a greater height and can better semi-enclose the first dielectric isolation structure 131 adjacent to the second dielectric isolation structure 132, so that the second dielectric isolation structure 132 farther away from the drain region 150 can better form a further blocking effect to prevent the interface charges from being extracted, so as to effectively improve the lateral voltage withstand capability of the semiconductor device.

In some other embodiments of the present disclosure, referring to FIG. 2 and FIG. 3, a length of the barrier portion 1302 of the second dielectric isolation structure 132 protruding from the insulating buried layer 112 and bending towards the drain region 150 is greater than that of the barrier portion 1302 of the first dielectric isolation structure 131 protruding from the insulating buried layer 112 and bending towards the drain region 150. The length of the barrier portion 1302 refers to a dimension of the barrier portion 1302 in the direction towards the drain region 150 (in the embodiments as shown in FIG. 1, the direction in which the barrier portion 1302 faces the drain region 150 is parallel to an x-axis direction). In this way, the length of the barrier portion 1302 of the second dielectric isolation structure 132 is longer, so that the interface charges between the first dielectric isolation structure 131 adjacent to the second dielectric isolation structure 132 and the insulating buried layer 112 can be more easily blocked by the barrier portion 1302 of the second dielectric isolation structure 132 during extraction, so as to effectively improve the lateral voltage withstand capability of the semiconductor device.

In some other embodiments of the present disclosure, referring to FIG. 2 and FIG. 3, a height of the support portion 1301 of the second dielectric isolation structure 132 protruding from the insulating buried layer 112 and bending towards the drain region 150 is greater than that of the support portion 1301 of the first dielectric isolation structure 131 protruding from the insulating buried layer 112 and bending towards the drain region 150; and a length of the barrier portion 1302 of the second dielectric isolation structure 132 protruding from the insulating buried layer 112 and bending towards the drain region 150 is greater than that of the barrier portion 1302 of the first dielectric isolation structure 131 protruding from the insulating buried layer 112 and bending towards the drain region 150. With such arrangement, the lateral voltage withstand capability and the vertical voltage withstand capability of the semiconductor device can be improved.

In some embodiments of the present disclosure, each dielectric isolation structure 130 protruding from the insulating buried layer 112 and bending toward the drain region 150 extends through the drift region 120 in a z-axis direction, so that projections of the plurality of dielectric isolation structures 130 on the insulating buried layer 112 cover more areas, which can improve a blocking effect of the plurality of dielectric isolation structures 130 on the interface charges formed on the upper surface of the insulating buried layer 112.

In some embodiments of the present disclosure, dielectric constants of at least two dielectric isolation structures 130 gradually decrease in the direction towards the drain region 150.

Wording “dielectric constants of the at least two dielectric isolation structures 130 gradually decrease in the direction towards the drain region 150” means that the concentration of the drift region 120 gradually changes, which increases electric field integral of the drift region 120 and further increases the breakdown voltage of the semiconductor device without increasing resistance.

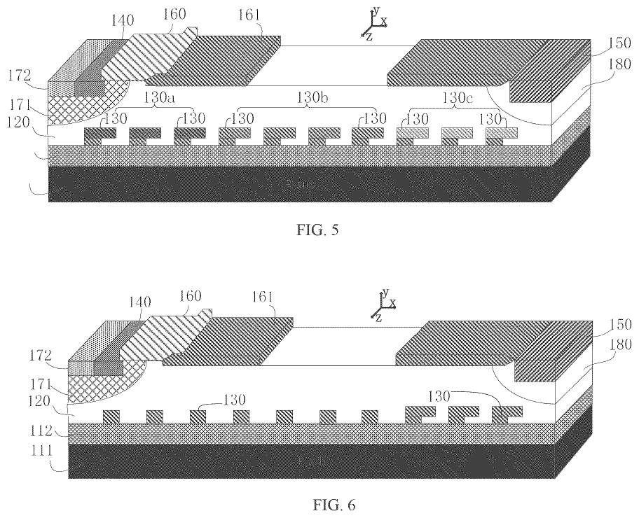

In some other embodiments of the present disclosure, referring to FIG. 5, the plurality of the dielectric isolation structures 130 are arranged to form a first dielectric isolation group 130a, a second dielectric isolation group 130b, and a third dielectric isolation group 130c spaced apart in the direction towards the drain region 150. The dielectric constant of each dielectric isolation structure 130 in the first dielectric isolation group 130a is greater than that of each dielectric isolation structure 130 in the second dielectric isolation group 130b, and the dielectric constant of each dielectric isolation structure 130 in the second dielectric isolation group 130b is greater than that of each dielectric isolation structure 130 in the third dielectric isolation group 130c.

With such arrangement, the concentration of the drift region 120 gradually changes, which increases electric field integral of the drift region 120, and further increases the breakdown voltage of the semiconductor device without increasing resistance.

In some embodiments, as shown in FIG. 5, the dielectric isolation structures 130 of the first dielectric isolation group 130a are made of high-K dielectric, the dielectric isolation structures 130 of the second dielectric isolation group 130b are made of silicon dioxide, and the dielectric isolation structures 130 of the third dielectric isolation group 130c are made of low-K dielectric.

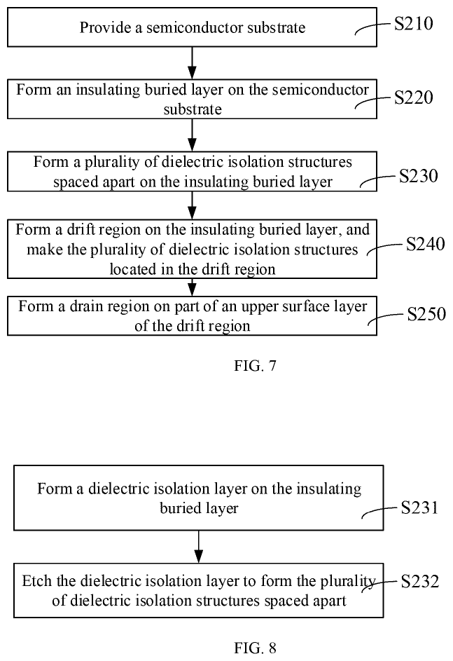

A manufacturing method for a semiconductor device in the present disclosure is described below with reference to FIG. 7 to FIG. 10.

In some embodiments of the present disclosure, referring to FIG. 7, the manufacturing method for a semiconductor device includes the following steps.

At S210, a semiconductor substrate is provided.

At S220, an insulating buried layer is formed on the semiconductor substrate.

At S230, a plurality of dielectric isolation structures spaced apart are formed on the insulating buried layer.

At S240, a drift region is formed on the insulating buried layer, where the plurality of dielectric isolation structures are located in the drift region.

At S250, a drain region is formed on part of an upper surface layer of the drift region.

The plurality of dielectric isolation structures are spaced apart in a direction towards the drain region, and at least one of the dielectric isolation structures protrudes from the insulating buried layer and bends towards the drain region.

On the one hand, when in use, the semiconductor device in the present disclosure can increase the dielectric electric field of the insulating buried layer, and at the same time, due to the shielding effect of the interface charges, the strong electric field in the drain region is reduced, which prevents the source region from being broken down before the electric field of the drain region rises, helping improve a lateral voltage withstand capability of the semiconductor device. On the other hand, the plurality of dielectric isolation structures are spaced apart in the drift region in a direction towards the drain region. It may be understood that the dielectric isolation structure protruding from the insulating buried layer and bending towards the drain region is equivalent to a layer of SOI structure, so that the dielectric isolation structure and the insulating buried layer can form a dual dielectric withstand voltage layer, which can greatly improve a vertical voltage withstand capability of the semiconductor device. Therefore, by use of the plurality of dielectric isolation structures, the lateral voltage withstand capability and the vertical voltage withstand capability of the semiconductor device can be improved, and a breakdown voltage of the semiconductor device can be ultimately increased.

In some embodiments, the first conductivity type is P type, and the second conductivity type is N type. Correspondingly, the semiconductor substrate is a P-type silicon substrate, and the drift region is an N-type drift region. In other embodiments, the first conductivity type may be N type, and the second conductivity type may be P type.

In some embodiments, the insulating buried layer may be manufactured by oxygen injection oxidation or bonding.

In some embodiments, the insulating buried layer is made of a silicon oxide, such as silicon dioxide.

In some embodiments, the drift region is realized by high-temperature drive-in after implantation, and certain doping concentration is required to ensure a current path.

In some embodiments, the dielectric isolation structure may be manufactured by oxygen injection oxidation or bonding. The dielectric isolation structure is made of a silicon oxide, such as silicon dioxide.

It should be noted that the structures such as the first well region, the source region, the drain region, the first well region lead-out region, the second well region, the gate structure, and the field oxide layer of the semiconductor device provided in the present disclosure are all formed using a conventional manufacturing method for a LDMOS device. Details thereof are not described herein again. Formation processes of “the plurality of dielectric isolation structures” and the drift region of the semiconductor device provided in the present disclosure are mainly described below.

In some embodiments of the present disclosure, referring to FIG. 8, step S230 of forming the plurality of dielectric isolation structures spaced apart on the insulating buried layer includes the following steps.

At S231, a dielectric isolation layer is formed on the insulating buried layer.

At S232, the dielectric isolation layer is etched to form the plurality of dielectric isolation structures spaced apart.

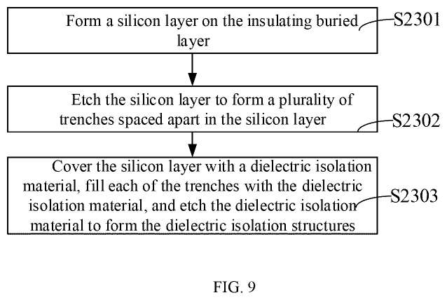

In some other embodiments of the present disclosure, referring to FIG. 9, step S230 of forming the plurality of dielectric isolation structures spaced apart on the insulating buried layer includes the following steps.

At S2301, a silicon layer is formed on the insulating buried layer.

At S2302, the silicon layer is etched to form a plurality of trenches spaced apart in the silicon layer.

At S2303, the silicon layer is covered with a dielectric isolation material, each of the trenches is filled with the dielectric isolation material; and the dielectric isolation material is etched to form the dielectric isolation structures.

in covering the silicon layer with the dielectric isolation material and filling each of the trenches with the dielectric isolation material, the silicon layer may be covered with the dielectric isolation material by growth or deposition, and certainly, each of the trenches may also be filled with the dielectric isolation material by growth or deposition, which is not specifically limited herein.

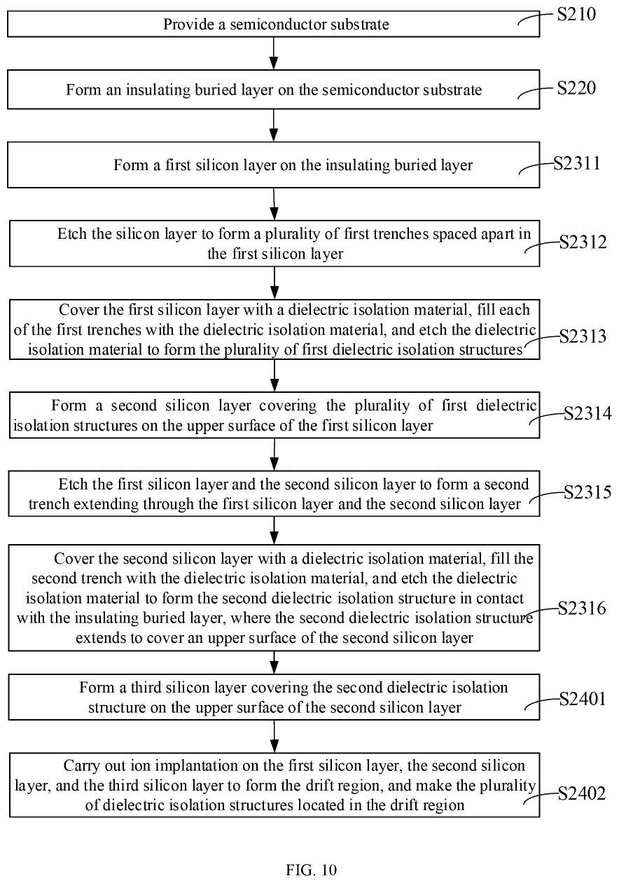

In some other embodiments, the plurality of dielectric isolation structures include a plurality of first dielectric isolation structures and one second dielectric isolation structure. Referring to FIG. 10, step S230 of forming the plurality of dielectric isolation structures spaced apart on the insulating buried layer includes the following steps.

At S2311, a first silicon layer is formed on the insulating buried layer.

At S2312, the first silicon layer is etched to form a plurality of first trenches spaced apart in the first silicon layer.

At S2313, the first silicon layer is covered with a dielectric isolation material, each of the first trenches is filled with the dielectric isolation material; and the dielectric isolation material is etched to form the plurality of first dielectric isolation structures. Each first dielectric isolation structure extends to cover an upper surface of the first silicon layer.

At S2314, a second silicon layer covering the plurality of first dielectric isolation structures is formed on the upper surface of the first silicon layer.

At S2315, the first silicon layer and the second silicon layer are etched to form a second trench extending through the first silicon layer and the second silicon layer.

At S2316, the second silicon layer is covered with a dielectric isolation material, the second trench is filled with the dielectric isolation material; and the dielectric isolation material is etched to form the second dielectric isolation structure in contact with the insulating buried layer, where the second dielectric isolation structure extends to cover an upper surface of the second silicon layer.

In this embodiment, referring to FIG. 10, step 240 of forming the drift region on the insulating buried layer, and enabling the plurality of dielectric isolation structures to be located in the drift region includes the following steps.

At S2401, a third silicon layer covering the second dielectric isolation structure is formed on the upper surface of the second silicon layer.

At S2402, ion implantation is carried out on the first silicon layer, the second silicon layer, and the third silicon layer to form the drift region, and the plurality of dielectric isolation structures are located in the drift region.

The embodiments shown in FIG. 10 illustrate an example in which the plurality of dielectric isolation structures include the plurality of first dielectric isolation structures and one second dielectric isolation structure. If the plurality of dielectric isolation structures include the plurality of first dielectric isolation structures and a plurality of second dielectric isolation structures, formation processes of the plurality of first dielectric isolation structures and the plurality of second dielectric isolation structures may also be obtained with reference to the formation processes of the plurality of first dielectric isolation structures and the second dielectric isolation structure in the embodiments shown in FIG. 10. Details thereof are not described herein again.

According to the semiconductor device manufactured by the manufacturing method for the semiconductor device, on the one hand, when a reverse bias voltage is applied to the semiconductor device, a depletion layer formed by the first well region and the drift region may merge with a depletion layer formed by the insulating buried layer and the drift region, an interface inversion layer may also be formed on an upper surface of the insulating buried layer, and interface charges are formed in the interface inversion layer. Since the dielectric isolation structure is configured to block the interface charges formed on the upper surface of the insulating buried layer between two adjacent dielectric isolation structures and configured to block the interface charges between the dielectric isolation structure and the insulating buried layer, the interface charges in the interface inversion layer can be blocked between two adjacent dielectric isolation structures and between the dielectric isolation structure and the insulating buried layer. In addition, the second dielectric isolation structure closer to the first well region can better form a further blocking effect, which can better block the interface charges between the second dielectric isolation structure and the first dielectric isolation structure adjacent to the second dielectric isolation structure, thereby better preventing extraction of the interface charges. Based on the interface Gauss theorem, it can be seen that the interface charges directly affect the electric field of the dielectric layer, compared with the semiconductor device without the dielectric isolation structure, the semiconductor device in the present disclosure, when in use, can increase the dielectric electric field of the insulating buried layer, and at the same time, due to the shielding effect of the interface charges, the strong electric field in the drain region is reduced, which prevents the source region from being broken down before the electric field of the drain region rises, helping improve the lateral voltage withstand capability of the semiconductor device. On the other hand, the plurality of dielectric isolation structures are spaced apart in the drift region in the direction in which the first well region directs to the drain region. It may be understood that one dielectric isolation structure protruding from the insulating buried layer and bending towards the drain region is equivalent to a layer of SOI structure, so that the dielectric isolation structure and the insulating buried layer can form a dual dielectric withstand voltage layer, which can greatly improve the vertical voltage withstand capability of the semiconductor device.

It should be understood that, although the steps in the flowcharts in the above embodiments are shown in sequence as indicated by the arrows, the steps are not necessarily performed in the order indicated by the arrows. Unless otherwise clearly specified herein, the steps are performed without any strict sequence limitation, and may be performed in other orders. In addition, at least some steps in the above flowcharts may include a plurality of sub-steps or a plurality of stages, and such sub-steps or stages are not necessarily performed at a same moment, and may be performed at different moments. The sub-steps or stages are not necessarily performed in sequence. The sub-steps or stages and at least some of other steps or sub-steps or stages of other steps may be performed in turn or alternately. It should be noted that the above different embodiments may be combined with each other.

The technical features in the above embodiments may be randomly combined. For concise description, not all possible combinations of the technical features in the above embodiments are described. However, all the combinations of the technical features are to be considered as falling within the scope described in this specification provided that they do not conflict with each other.

The above embodiments only describe several implementations of the present disclosure, and description thereof is specific and detailed, but cannot therefore be understood as a limitation on the patent scope of the present disclosure. It should be noted that those of ordinary skill in the art may further make variants and improvements without departing from the conception of the present disclosure, and these all fall within the protection scope of the present disclosure. Therefore, the patent protection scope of the present disclosure should be subject to the appended claims.

1. A semiconductor device, comprising:
a semiconductor substrate;
an insulating buried layer located on the semiconductor substrate;
a drift region located on the insulating buried layer, part of an upper surface layer of the drift region being provided with a drain region; and
a plurality of dielectric isolation structures located in the drift region and on the insulating buried layer, and the plurality of dielectric isolation structures being spaced apart in a direction towards the drain region, at least one of the dielectric isolation structures protruding from the insulating buried layer and bending towards the drain region.

2. The semiconductor device according to claim 1, wherein each of the dielectric isolation structures protrudes from the insulating buried layer and bends towards the drain region.

3. The semiconductor device according to claim 1, wherein each dielectric isolation structure protruding from the insulating buried layer and bending towards the drain region comprises a support portion and a barrier portion; and
wherein an end of the support portion is in direct contact with the insulating buried layer, another end of the support portion is connected to an end of the barrier portion; another end of the barrier portion bends and extends towards the drain region; and the barrier portion is spaced apart from the insulating buried layer.

4. The semiconductor device according to claim 3, wherein the barrier portion is parallel to the insulating buried layer.

5. The semiconductor device according to claim 3, wherein the support portion and the barrier portion are connected in an arc shape or perpendicularly.

6. The semiconductor device according to claim 2, wherein the plurality of dielectric isolation structures comprise a plurality of first dielectric isolation structures and at least one second dielectric isolation structure, wherein heights of the first dielectric isolation structures are all less than a height of the at least one second dielectric isolation structure; the at least one second dielectric isolation structure is arranged on a side of the plurality of dielectric isolation structures away from the drain region; and the second dielectric isolation structure semi-encloses at least one of the first dielectric isolation structures.

7. The semiconductor device according to claim 6, wherein the plurality of dielectric isolation structures comprise a plurality of second dielectric isolation structures, and wherein heights of the second dielectric isolation structures gradually increase in a direction away from the drain region.

8. The semiconductor device according to claim 6, wherein a projection of each second dielectric isolation structure on the insulating buried layer has an overlapping region with a projection of at least one of the first dielectric isolation structures adjacent to the second dielectric isolation structure on the insulating buried layer.

9. The semiconductor device according to claim 6, wherein each of the dielectric isolation structures comprises a support portion and a barrier portion; and
wherein an end of the support portion is in direct contact with the insulating buried layer, another end of the support portion is connected to an end of the barrier portion; another end of the barrier portion bends and extends towards the drain region; and the barrier portion is spaced apart from the insulating buried layer; and
a height of the support portion of the second dielectric isolation structure is greater than that of the support portion of the first dielectric isolation structure; the height of the support portion is a dimension of the support portion in a thickness direction of the semiconductor device.

10. The semiconductor device according to claim 6, wherein each of the dielectric isolation structures comprises a support portion and a barrier portion; and
wherein an end of the support portion is in direct contact with the insulating buried layer, another end of the support portion is connected to an end of the barrier portion; another end of the barrier portion bends and extends towards the drain region; and the barrier portion is spaced apart from the insulating buried layer; and
a length of the barrier portion of the second dielectric isolation structure is greater than that of the barrier portion of the first dielectric isolation structure; the length of the barrier portion is a dimension of the barrier portion in the direction towards the drain region.

11. The semiconductor device according to claim 1, wherein dielectric constants of at least two of the dielectric isolation structures gradually decrease in the direction towards the drain region; or
the plurality of the dielectric isolation structures are arranged to form a first dielectric isolation group, a second dielectric isolation group, and a third dielectric isolation group that are spaced apart in the direction towards the drain region, wherein a dielectric constant of each of the dielectric isolation structures in the first dielectric isolation group is greater than that of each of the dielectric isolation structures in the second dielectric isolation group; and the dielectric constant of each of the dielectric isolation structures in the second dielectric isolation group is greater than that of each of the dielectric isolation structures in the third dielectric isolation group.

12. The semiconductor device according to claim 1, further comprising:
a first well region and a second well region that are arranged on part of the upper surface layer of the drift region;
a first well region lead-out region and a source region that are arranged on an upper surface layer of the first well region; the first well region lead-out region being short-circuited with potential of the source region, and the drain region being arranged on an upper surface layer of the second well region; and
a gate structure arranged on the first well region, having an end extending to be above the drift region and another end extending to be above the source region;
wherein all the dielectric isolation structures are arranged between the source region and the drain region; and
the first well region and the first well region lead-out region have a first conductivity type; the drift region, the second well region, the source region, and the drain region have a second conductivity type; and the first conductivity type and the second conductivity type are opposite.

13. A manufacturing method for a semiconductor device, comprising:
providing a semiconductor substrate;
forming an insulating buried layer on the semiconductor substrate;
forming a plurality of dielectric isolation structures spaced apart on the insulating buried layer;
forming a drift region on the insulating buried layer, and enabling the plurality of dielectric isolation structures to be located in the drift region; and
forming a drain region on part of an upper surface layer of the drift region;
wherein the plurality of dielectric isolation structures are spaced apart in a direction towards the drain region, and at least one of the dielectric isolation structures protrudes from the insulating buried layer and bends towards the drain region.

14. The manufacturing method according to claim 13, wherein forming the plurality of dielectric isolation structures spaced apart on the insulating buried layer comprises:
forming a dielectric isolation layer on the insulating buried layer; and
etching the dielectric isolation layer to form the plurality of dielectric isolation structures spaced apart.

15. The manufacturing method according to claim 13, wherein forming the plurality of dielectric isolation structures spaced apart on the insulating buried layer comprises:
forming a silicon layer on the insulating buried layer;
etching the silicon layer to form a plurality of trenches spaced apart in the silicon layer; and
covering the silicon layer with a dielectric isolation material, filling each of the trenches with the dielectric isolation material, and etching the dielectric isolation material to form the dielectric isolation structures.
